(19) United States
(12) Patent Application Publication
(10) Pub. No.: US 2026/0312494 A1
(43) Pub. Date: Oct. 8, 2026

(54) PRE-CHARGE CIRCUIT WITH DIFFERENTIAL INPUTS AND OUTPUTS

(71) Applicant: Infineon Technologies AG, Neubiberg (DE)

(72) Inventor: Peter Bogner, Wernberg (AT)

(21) Appl. No.: 19/563,956

(22) Filed: Mar. 11, 2026

(30) Foreign Application Priority Data
Apr. 7, 2025 (DE) 102025113601.7

(51) Int. Cl. H02M 3/07; H02M 1/00

(52) U.S. Cl. CPC H02M 3/07; H02M 1/0006; H02M 1/0012

(57) ABSTRACT

An electronic circuit is described herein. In one embodiment, the circuit includes a differential input including a first input node and a second input node and coupled, during operation, to an input capacitor; a differential output including a first output node and a second output node and coupled, during operation, to an output capacitor; a first switch coupled between the first input node and the first output node; a pre-charge circuit configured to inject charge at the first output node; and control circuit configured to switch the first switch on and off and to control the pre-charge circuit to inject charge at the first output node while the first switch is off. The circuit may be used to pre-charge an input capacitance of another circuit which is coupled to the differential output.

### TECHNICAL FIELD

This invention relates to the field of voltage measurement, in particular voltage monitoring with an analog-to-digital converter (ADC).

### BACKGROUND

Voltage measurement has, besides accuracy, several requirements. One challenge is electromagnetic interference (EMI) which may distort the voltage measurement. This issue is usually addressed by the provision of a filter, in order to suppress high frequency disturbances. In the case of switched capacitor ADCs (e.g. an SAR ADC, Successive-approximation ADC), the sampling is accomplished by means of one or more buffer capacitors (hereinafter referred to as sampling capacitors) and a switch. When using a switched capacitor ADC, a capacitive current (displacement current) occurs during the sampling phase. The capacitive current depends on the size of the sampling capacitor, the voltage difference between input voltage and voltage across the sampling capacitor at the start time of the sampling process and the sampling frequency.

To avoid undesired aliasing and suppress disturbances (e.g. caused by EMI), a filter can be implemented in front of the sampling capacitor and switch. This filter can be placed on-chip or implemented as an external circuit and usually comprises a filter capacitance. An external filter usually entails additional cost for the external components and the additional space on a printed circuit board (PCB). Further, the capacitance of the external filter must be large enough so that the error introduced in the sampling phase by charging the sampling capacitor is low, since during the sampling phase charge is transferred from the filter capacitance to the sampling capacitance. Internal (on chip) filters need to be kept low in area and therefore small filter capacitances must be used. A buffer may be placed after the filter to prevent taking charge from the filter capacitor to charge the sampling capacitor. Buffers need to fulfill sampling speed requirements and consume power and chip area. They may also introduce offset and noise and reduce measurement accuracy.

There is a need for a technique which allows for small (internal) filters while maintaining full measurement accuracy, without the deficiencies outlined above.

### SUMMARY

An electronic circuit is described herein. In one embodiment, the circuit includes a differential input including a first input node and a second input node and coupled, during operation, to an input capacitor; a differential output including a first output node and a second output node and coupled, during operation, to an output capacitor; a first switch coupled between the first input node and the first output node; a pre-charge circuit configured to inject charge at the first output node; and control circuit configured to switch the first switch on and off and to control the pre-charge circuit to inject charge at the first output node while the first switch is off. The circuit may be used to pre-charge an input capacitance of another circuit which is coupled to the differential output.

A corresponding pre-charging method includes, according to one embodiment, switching a first switch coupled between a first input node and a first output node on and off, wherein the first input node and a second input node form a differential input coupled to an input capacitor, and wherein the first output node and a second output node form a differential output coupled to an output capacitor. The method further includes controlling a pre-charge circuit to inject charge at the first output node while the first switch is off.

### BRIEF DESCRIPTION OF THE DRAWINGS

The embodiments described herein can be better understood with reference to the following description and drawings. The components in the figures are not necessarily to scale, emphasis instead being placed upon illustrating the principles of the embodiments. Furthermore, in the figures, like reference numerals designate corresponding parts. In the drawings:

FIG. 1 illustrates the basic structure of an electronic circuit for sampling an input voltage including a circuit for precharging the sampling capacitors (pre-charge circuit).

FIG. 2 illustrates one embodiment of an electronic circuit with a first charge pump and a logic control circuit.

FIG. 3 illustrates a switching scheme for the circuit of FIG. 2 and a signal curve of a corresponding voltage signal.

FIG. 4 illustrates the example of FIG. 2 in more detail.

FIG. 5 illustrates a modification of the example of FIG. 2.

FIG. 6 illustrates a switching scheme for the circuit of FIG. 5 and a signal curve of a corresponding voltage signal.

FIG. 7 illustrates an alternative switching scheme for the circuit of FIG. 5 and a signal curve of a corresponding voltage signal.

FIG. 8 illustrates a modification of the example of FIG. 5.

FIG. 9 illustrates a modification of the example of FIG. 1.

FIG. 10 is a flow chart illustrating a method that may be used to pre-charge a capacitor.

### DETAILED DESCRIPTION

Switched capacitor ADCs include a sample and hold circuit with a sampling capacitor and a switch. At the beginning of a sampling phase, the sampling capacitor is coupled (via the switch) to an input node, at which an input voltage is provided. If the input voltage is provided by a filter with a filter capacitance (i.e. if the input node of the sample and hold circuit is connected to the filter output), charge may be transferred during the sampling phase from the filter capacitance to the sampling capacitor which will influence the measurement. In order to prevent or reduce this charge transfer, the sampling capacitor may be charged prior to the sampling phase. For this purpose, a pre-charge buffer may provide charge to the sampling capacitor in a first phase, whereas subsequently, in a second phase, the sampling capacitor is coupled to the input node. In the second phase, the filter capacitance then only needs to provide a much smaller amount of charge (ideally zero) to the sampling capacitor.

In many applications, a differential voltage measurement is required. For example, when measuring a voltage drop across a high-side power transistor, a relatively low differential voltage (e.g. less than 1V) is to be measured, wherein the common mode voltage can be comparably large (e.g. −20V to 60V).

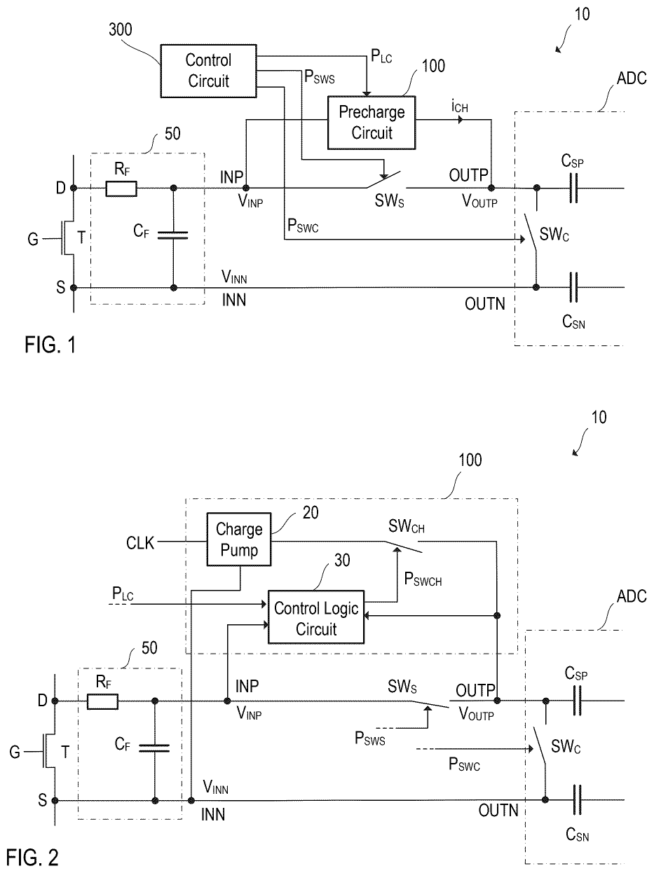

FIG. 1 illustrates the basic structure of an electronic circuit 10 including a pre-charge circuit 100. The electronic circuit 10 comprises a differential input formed by a first input node INP and a second input node INN. In this context, “differential input” means that the two input nodes INP and INN are floating (not ground-related) input nodes. The sought information is the differential input voltage V_{INP}−V_{INN}, while the common mode voltage (e.g. defined as (V_{INP}+V_{INN})/2) may be significantly larger (by orders of magnitude) than the differential voltage and vary significantly. The differential input may be coupled to a filter 50, which may consist of an RC-circuit with an input resistance R_{F} and a filter capacitor C_{F}. The input of the filter 50 may be coupled to an electronic component, such as a MOSFET T. In the depicted example, the filter 50 is coupled to the load path of MOSFET T and, therefore, the drain-source voltage V_{DS} is the (differential) input voltage “seen” by the filter 50. Accordingly, in the present example, the filtered input voltage is the differential input voltage applied to the differential input (nodes INP, INN) of the electronic circuit 10. It is understood that the concepts described herein are not limited to MOSFETs or other types of electronic switches such as bipolar junction transistors (BJTs) or insulated gate bipolar transistors (IGBTs) junction field-effect transistors (JEFTs). In fact, the transistor T may also be replaced by other electronic components such as a (shunt) resistor for example.

The electronic circuit 10 further includes a differential output formed by a first output node OUTP and a second output node OUTN. In this context, “differential output” means that the two output nodes OUTP and OUTN are floating (not ground-related) output nodes. In the examples described herein, the second input node INN and second output node OUTN may be connected by a low-ohmic line. The first input node INP and the first output node OUTP may be coupled via a first switch SW_{S}, which may be implemented, e.g., by a MOSFET. The differential output of the electronic circuit 10 is coupled to an output capacitance, which is, in the depicted example formed by a first output capacitor C_{SP} coupled to the first output node OUTP, and a second output capacitor C_{SN} coupled to the second output node OUTN. Between the first output node OUTP and second output node OUTN a further switch SW_{C} (hereinafter referred to as conversion switch) may be provided. The first output capacitor C_{SP}, the second output capacitor C_{SN} and the conversion switch SW_{C} may be part of an analog-to-digital converter ADC. wherein the first and/or second output capacitors C_{SP} and C_{SN} form the input capacitance of the analog-to-digital converter (which, at the same time, is the output capacitance of the electronic circuit 10).

The electronic circuit 10 depicted in FIG. 1 further comprises the pre-charge circuit 100, which is coupled to the first input node INP and the first output node OUTP. The pre-charge circuit 100 is configured to provide a charging current i_{CH} to (and thus to inject charge into) the first output node OUTP. The electronic circuit 10 of FIG. 1 further comprises a control circuit 300 that is configured to control the operation of the switch SW_{S} and the pre-charge circuit 100. The control circuit 300 is configured to switch the first switch SW_{S} on and off via a first control signal P_{SWS}. The first switch SW_{S} may be a transistor (e.g. a MOSFET) and a suitable driver circuit may be needed in order to switch the first switch SW_{S} on and off. The same applies accordingly to other switches described herein later. It is understood that also for those switches, driver circuits may be needed to reliably switch them on and off. As suitable driver circuits are as such known, they will not be discussed herein in more detail. The control circuit 300 is further configured to control, via a second control signal P_{LC}, the pre-charge circuit 100 to provide the charging current i_{CH} to (i.e. to inject charge into) the first output node OUTP. The control circuit 300 may also be configured to switch the conversion switch SW_{C} on and off via a third control signal P_{SWC}.

In one example, the control circuit 300 may be implemented as a state machine with dedicated logic elements, that may be configured to perform the functions outlined above. In some examples, the control circuit 300 may be implemented using one or more microprocessors, digital signal processors (DSPs), application specific integrated circuits (ASICs), field programmable gate arrays (FPGAs), or any other equivalent integrated or discrete logic circuitry, as well as any combinations of such components. In some examples, controller may include a memory, which may be random access memory (RAM), read only memory (ROM), programmable read only memory (PROM), erasable programmable read only memory (EPROM), electronically erasable programmable read only memory (EEP-ROM), flash memory, comprising executable instructions for causing the one or more processors to perform the actions attributed to them. Accordingly, the functions provided by the control circuit 300 may be implemented using hardware, software, or a combination thereof. The control circuit 300, or parts thereof, may also be part of a control unit of the ADC.

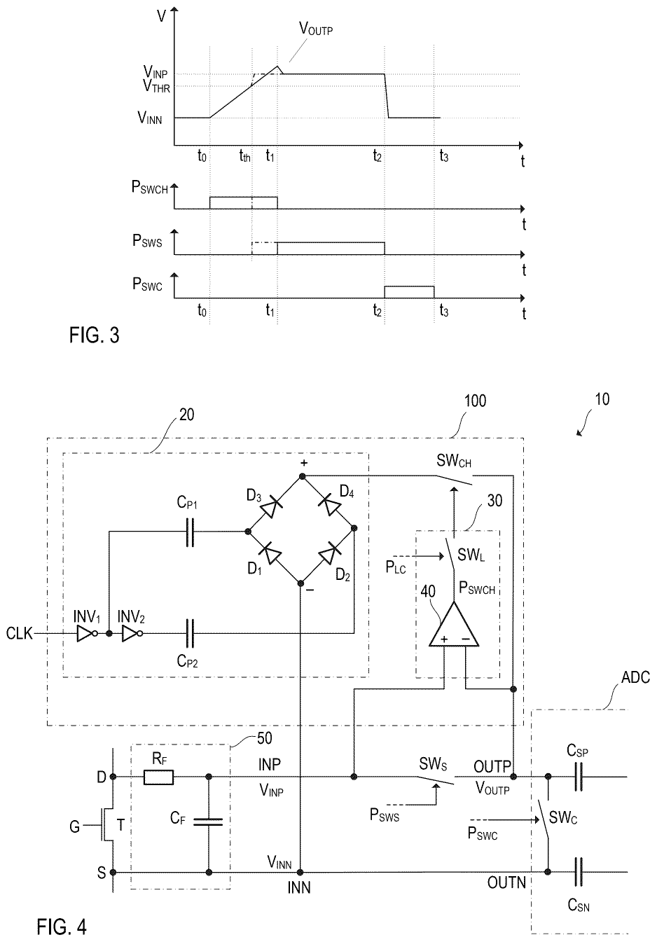

The circuit of FIG. 2 is basically the same as in FIG. 1, but showing an example of the pre-charge circuit 100 in more detail. The control circuit 300 is not shown in FIG. 2 to keep the illustration simple. The pre-charge circuit 100 depicted in FIG. 2 comprises a first charge pump 20, a control logic circuit 30 and a second switch SW_{CH}. The first charge pump 20 may be coupled to the first output node OUTP via the second switch SW_{CH}. The first charge pump 20 is also coupled to the second input node INN and it has a clock input for receiving a clock signal CLK. The clock signal CLK may be provided by an external circuity. The control logic circuit 30 is coupled to the first input node INP and first output node OUTP. Further, the control logic circuit 30 is configured to switch the second switch SW_{CH} on and off via a fourth control signal P_{SWCH}. When the second switch SW_{CH} is closed, the first charge pump 20 can inject charge at the first output node OUTP in each period of the clock signal CLK. In other words, the second switch SW_{CH} activates or deactivates the first charge pump 20. The control logic circuit 30 is also configured to receive the second control signal P_{LC}, which triggers a pre-charge process (cf. FIG. 3). In an alternative example, the charge pump 20 is activated and deactivated by enabling and disabling the clock signal CLK received by the charge pump 20. In this case, the switch SW_{CH} may not be needed. The control logic circuit 30 may also be part of the control circuit 300, but is depicted as a separate element for a better understanding in FIG. 2.

When measuring a differential voltage (e.g. V_{INP}−V_{INN}) with a switched capacitor ADC, the measuring is conducted in two phases. First, in a sampling phase, the sampling capacitors (e.g. C_{SP}, C_{SN}) sample (using a sampling switch) the differential voltage, which means that the differential voltage is “held” (stored) and by means of the sampling capacitors at the sampling time instant (hence the name sample and hold circuit). Second, in a conversion phase, the sampled differential voltage is converted into a digital signal representing the sampled differential voltage. In the example of FIG. 2, a first input voltage V_{INP} at the first input node INP is sampled, in the sampling phase, via the first output capacitor C_{SP}, and a second input voltage V_{INN} at the second input node INN is sampled via the second output capacitor C_{SN}. In essence, the differential voltage V_{INP}−V_{INN} is stored by the capacitors C_{SP} and C_{SN}. During the sampling phase, the first switch SW_{S} is closed in order to connect the first output capacitor C_{SP} to the first input node INP to receive the first input voltage V_{INP}. However, since closing the switch SW_{S} immediately at the beginning of the sampling phase would introduce a measurement error for the reasons outlined above, the first switch SW_{S} may not be closed until the first output capacitor C_{SP} is pre-charged. At the beginning of the conversion phase, the first switch SW_{S} is opened and the conversion switch SW_{C} is closed for the analog-to-digital conversion to begin. It is noted that various analog-to-digital conversion techniques are as such known and thus not further discussed herein. As mentioned, the precharging concept described herein may be useful at least in connection with analog-to-digital converters that have an input capacitance storing the (differential) voltage to be digitized. However, the precharging concept may also be used for other applications, such as a switched capacitor amplifier for example, where no digitized value is to be derived.

FIG. 3 illustrates a switching scheme for the electronic circuit 10 of FIG. 2. The first (top) diagram depicts the signal curve(s) of a first output voltage V_{OUTP} at the first output node OUTP. The second, third and fourth diagrams show the switching signals P_{SWCH}, P_{SWS} and, respectively, P_{SWC} for the switches SW_{CH}, SW_{S} and SW_{C}. Before a time instant t₀, the first output voltage V_{OUTP} is equal to the second input voltage V_{INN} present at the second input node INN, because the conversion switch SW_{C} short-circuited the nodes OUTP and OUTN (and thus also OUTP and INN) in the preceding conversion cycle. At time instant t₀, the second switch SW_{CH} is turned on by the fourth control signal P_{SWCH} thus connecting the first charge pump 20 to the first output node OUTP. Therefore, the first charge pump 20 injects charge at the first output node OUTP and (pre-) charges the first output capacitor C_{SP}. This causes the voltage V_{OUTP} at the first output node OUTP to rise.

At time instant t₁, the first output voltage V_{OUTP} reaches the voltage level of the first input voltage V_{INP} present at the first input node INP. At that time instant, the control logic circuit 30 switches the second switch SW_{CH} off thus deactivating the charge pump and stopping charge injection at node OUTP. Further, at time instant t₁, the control circuit 300 switches the first switch SW_{S} on. It is understood that the first switch SW_{S} and second switch SW_{CH} do not necessarily switch at the same time, but there could be a short pause between switching the second switch SW_{CH} off and switching the first switch SW_{S} on. The same applies accordingly to other time instants, at which two switches are switched. It is understood that also for those time instants, there could be a short pause between two switching operations of two corresponding switches. Since the second switch SW_{CH} is only switched off when the first output voltage V_{OUTP} (approximately) reaches the first input voltage V_{INP}, there may be a slight overshoot of the first output voltage V_{OUTP} because of the latency of the logic control circuit 30. However, after the first switch SW_{S} is turned on, the first output node OUTP is connected to the first input node INP, and the first output voltage V_{OUTP} actually equals the first input voltage V_{INP}.

The control logic circuit 30 does not necessarily have to keep the second switch SW_{CH} on until the first output voltage V_{OUTP} reaches the first input voltage V_{INP}. In some embodiments, the control logic circuit 30 may also be configured to switch the second switch SW_{CH} off after the first output voltage V_{OUTP} reaches a threshold value V_{THR} (which happens at a time instant tₜₕ in the example of FIG. 3). The threshold value V_{THR} may be somewhat lower than the first input voltage V_{INP}, e.g. 80% of the first input voltage V_{INP}. The dashed-dotted lines shown in FIG. 3 illustrate the signal curve of voltage V_{OUTP} and the switching signals of P_{SWCH} and P_{SWS} for this case.

After the switch SW_{S} has been turned on, the sampling phase begins and the first output capacitor C_{SP} samples the first input voltage V_{INP}. At time instant t₂, when the sampling is completed, the output capacitor C_{SP} holds the first input voltage V_{INP} and the conversion phase may begin. For this, the control circuit 300 may be configured to switch the first switch SW_{S} off via the first control signal P_{SWS} and the conversion switch SW_{C} on via the third control signal P_{SWC}. After the conversion switch SW_{C} has been turned on, the first output node OUTP is coupled to the second output node OUTN, and the first output voltage V_{OUTP} equals the second output voltage V_{OUTN}. During the conversion phase, the ADC may convert the sampled differential voltage to a digital value representing the sampled differential voltage. After the conversion is complete, the control circuit 300 switches the conversion switch SW_{C} off at time instant t₃, and a new cycle may begin, repeating the process described above.

The circuit of FIG. 4 is basically the same like in FIG. 2, but showing an example of the first charge pump 20 and the control logic circuit 30 in more detail. The first charge pump 20 may comprise a diode bridge rectifier consisting of diodes D₁-D₄. The anodes of diodes D₁ and D₂ are coupled to the second input node INN and the cathodes of the diodes D₃ and D₄ are coupled to the first output node OUTP via the second switch SW_{CH}. The input of a first inverter INV₁ is configured to receive the clock signal CLK, and the output of the first inverter INV₁ is coupled to the anode of diode D₃ and the cathode of diode D₁ via a first pump capacitor C_{P1}. The input of a second inverter INV₂ is coupled to the output of the first inverter INV₁, and the output of the second inverter INV₂ is coupled to the anode of diode D₄ and the cathode of diode D₂ via a second pump capacitor C_{P2}. During operation of the first charge pump 20, the second switch SW_{CH} is closed and the switches SW_{S} and SW_{C} are open, as described above.

When the output of the first inverter INV₁ provides a high signal level (e.g. 5V), the first pump capacitor C_{P1} raises the voltage of the common circuit node of diodes D₁ and D₃. Diode D₃ becomes forward-biased and current can flow from capacitor C_{P1} to the first output node OUTP (thus (pre-) charging the capacitor C_{SP}). Subsequently, when the output of the first inverter INV₁ provides a low signal level (e.g. 0V), diode D₃ is reverse-biased again. When the output of the first inverter INV₁ provides a low signal level, the output of the second inverter INV₂ provides a high signal level (e.g. 5V), and the second pump capacitor C_{P2} raises the voltage of the common circuit node of diodes D₂ and D₄. Diode D₄ becomes forward-biased and current can flow from capacitor C_{P2} to the first output node OUTP to further (pre-) charge the capacitor C_{SP}. Subsequently, when the output of the second inverter INV₂ provides a low signal level (e.g. 0V), diode D₄ is reverse-biased again and a new cycle begins. Cycle after cycle the first output capacitor C_{SP} is gradually charged and thus the first output voltage V_{OUTP} rises accordingly. The first and second pump capacitors C_{P1} and C_{P2} also separate the voltage domain of the second input node INN from the inverters and the clock. Further, in some embodiments, the second switch SW_{CH} also is provided in front of the input of the first inverter INV₁ instead of between the cathodes of the diodes D₃ and D₄ and the first output node OUTP. The second switch SW_{CH} then would connect or disconnect the clock signal CLK from the input of the first inverter INV₁, and thus deactivate or activate the charge pump.

According to the example of FIG. 4 the control logic circuit 30 may comprise a comparator 40 and a switch SW_{L}. The non-inverting input of the comparator 40 is coupled to the first input node INP and the inverting input of the comparator 40 is coupled to the first output node OUTP. The output of the comparator 40 provides the fourth control signal P_{SWCH} and is coupled to the second switch SW_{CH} via the logic switch SW_{L}. As long as the first output voltage V_{OUTP} is lower than the first input voltage V_{INP}, the comparator 40 outputs the fourth control signal P_{SWCH} with a high level to turn the second switch SW_{CH} on. The switch SW_{L} between the output of comparator 40 and the second switch SW_{CH} is controlled by the second control signal P_{LC}. The fourth control signal P_{SWCH} will only switch the second switch SW_{CH} on when the logic switch SW_{L} is closed. In other words, the second control signal P_{LC} controls whether the fourth control signal P_{SWCH} is forwarded to and thus can control the first charge pump 20 according to the functions described above. Thus, the second control signal P_{LC} activates or deactivates the pre-charge circuit 100.

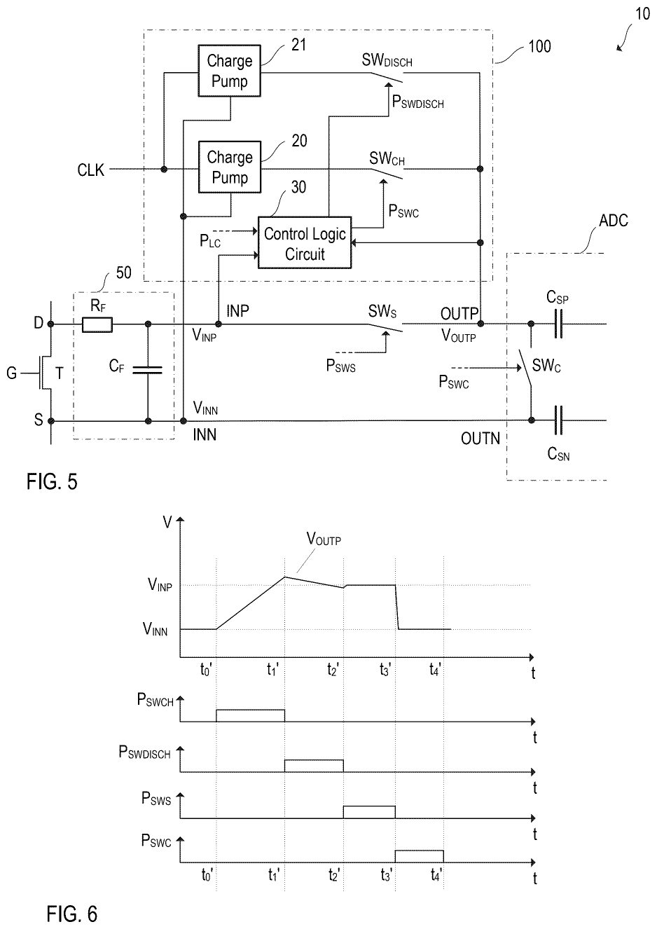

The circuit of FIG. 5 is basically the same like in FIG. 2, but with an additional second charge pump 21 and a third switch SW_{DISCH} provided in the pre-charge circuit 100. The second charge pump 21 is coupled to the first output node OUTP via the third switch SW_{DISCH}. The second charge pump 21 is also coupled to the second input node INN and (like the first charge pump 20) receives the clock signal CLK. The control logic circuit 30 is configured to switch the third switch SW_{DISCH} via a fifth control signal P_{SWDISCH}. When the third switch SW_{DISCH} is closed, the second charge pump 21 may sink charge from the first output node OUTP in accordance with the clock signal CLK. In other words, the third switch SW_{DISCH} activates or deactivates the second charge pump 21. Charge pumps configured to sink charge are as such known and are therefore not discussed herein in more detail.

FIG. 6 illustrates a switching scheme for the electronic circuit 10 of FIG. 5. The first (top) diagram depicts the signal curve of the first output voltage V_{OUTP} at the first output node OUTP. The second, third, fourth and fifth diagrams show the control signals P_{SWCH}, P_{SWDISCH}, P_{SWS} and P_{SWC} for the switches SW_{CH}, SW_{DISCH}, SW_{S} and SW_{C}, respectively. Before a time instant t₀′, the first output voltage V_{OUTP} is substantially equal to the second output voltage V_{OUTN} present at the second output node OUTN. At the time instant t₀′, the second switch SW_{CH} is turned on via the fourth control signal P_{SWCH} and the first charge pump 20 is connected to the first output node OUTP via the second switch SW_{CH}. The first charge pump 20 then injects charge at the first output node OUTP and charges the first output capacitor C_{SP}. As a consequence, the first output voltage V_{OUTP} rises. At a time instant t₁′, the first output voltage V_{OUTP} reaches the voltage level of the first input voltage V_{INP} present at the first input node INP. Since the second switch SW_{CH} is only switched off after the first output voltage V_{OUTP} reaches the first input voltage V_{INP}, there may be an overshoot of the first output voltage V_{OUTP} because of the latency of the logic control circuit 30. For this reason, the second charge pump 21 may be provided, in order to compensate for such an overshoot. At the time instant t₁′, the control logic circuit 30 turns the second switch SW_{CH} off and the third switch SW_{DISCH} on. Since the second charge pump 21 is configured to sink charge from the first output node OUTP, the capacitor C_{SP} is discharged and the first output voltage V_{OUTP} drops. The second charge pump 21 may be configured to provide a lower current than the first charge pump 20, meaning the rate of sinking the charge via the second charge pump 21 may be smaller than the rate of injecting the charge via the first charge pump 20. In other words, the first charge pump 20 may be configured to inject more charge at the first output node OUTP than the second charge pump 21 may be configured to sink from the first output node OUTP in equal time intervals.

At a time instant t₂′, the first output voltage V_{OUTP} drops below the first input voltage V_{INP}. This time, there may be a slight undershoot of the first output voltage V_{OUTP} because of the latency of the logic control circuit 30. The magnitude of the undershoot at time instant t₂′ is smaller than the magnitude of the overshoot at time instant t₁′ because of the different strengths of the first and second charge pumps 20 and 21. This results in a more accurately pre-charged first output capacitor C_{SP}. At time instant t₂′, the third switch SW_{DISCH} is turned off via the fifth control signal P_{SWDISCH}. Further, at time instant t₂′, the control circuit 300 is configured to switch the first switch SW_{S} on (sampling switch). After the switch SW_{S} has been turned on, the sampling phase begins and the first output capacitor C_{SP} samples the first input voltage V_{INP}. The switching scheme from here on is basically the same as in FIG. 3 and thus will not be described here again. It is understood, that the example of the control logic circuit 30 depicted in FIG. 4 cannot be used for this switching scheme. A logic control circuit providing the functions described above may be implemented with additional logic elements, but is not discussed in more detail herein. A skilled person will be able to design a control logic that provides the functions described with reference to FIG. 6.

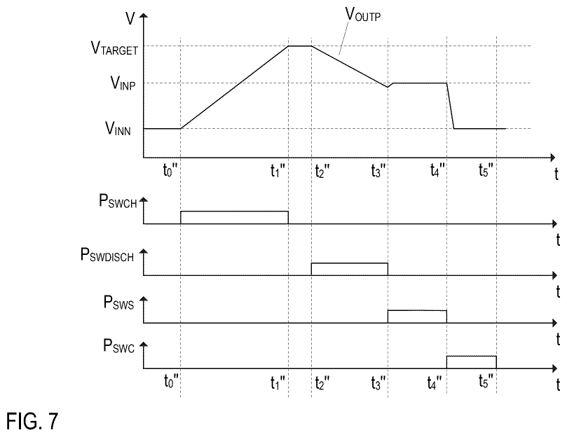

FIG. 7 illustrates an alternative switching scheme for the electronic circuit 10 of FIG. 5. The first (top) diagram depicts the signal curve of the first output voltage V_{OUTP} at the first output node OUTP. The second, third, fourth and fifth diagrams show the switching signals P_{SWCH}, P_{SWDISCH}, P_{SWS} and P_{SWC} for the switches SW_{CH}, SW_{DISCH}, SW_{S} and SW_{C}, respectively. Before time instant t₀″, the first output voltage V_{OUTP} is equal to the second input voltage V_{INN} present at the second input node INN. At time instant t₀″, the second switch SW_{CH} is turned on via the fourth control signal P_{SWCH} and the first charge pump 20 is connected to the first output node OUTP via the second switch SW_{CH}. The first charge pump 20 injects charge at the first output node OUTP and charges the first output capacitor C_{SP}. As a consequence, the first output voltage V_{OUTP} rises. The first output capacitor C_{SP} may be charged until the first output voltage V_{OUTP} reaches a target voltage V_{TARGET} at time instant t₁″. The target voltage V_{TARGET} may be higher than the first input voltage V_{INP}. At time instant t₁″, the control logic circuit 30 may turn the second switch SW_{CH} off.

After reaching the target voltage V_{TARGET}, at a time instant t₂″, the control logic circuit 30 may be configured to switch the third switch SW_{DISCH} on via the fifth control signal P_{SWDISCH}. The time instant t₂″ could also be the same as the time instance t₁″, but in the depicted example in FIG. 7 there is a pause time between time instants t₁″ and t₂″. After the third switch SW_{DISCH} has been switched on, the second charge pump 21 sinks charge from the first output node OUTP, the capacitor C_{SP} is thus discharged and the first output voltage V_{OUTP} drops. At time instant t₃″, when the first output voltage V_{OUTP} reaches V_{INP}, the control logic circuit 30 may switch the third switch SW_{DISCH} off.

Further, at time instant t₃″, the logic circuit 300 may switch the first switch SW_{S} (sampling switch) on via the first control signal P_{SWS}. After the switch SW_{S} has been turned on, the sampling phase begins and the first output capacitor C_{SP} samples the first input voltage V_{INP}. The switching scheme from here on is basically the same as in FIG. 3 and thus will not be described here again. It is understood, that if a switching scheme according to FIG. 7 is to be implemented, the second charge pump 21 does not necessarily need to have less strength (i.e. less output current) than the first charge pump 20, since it is not used for compensating for an overshoot in this case. Further, the control logic circuit 30 may be configured to switch the third switch SW_{DISCH} off and the logic circuit 300 may be configured to switch the first switch SW_{S} on at a different time instant than time instant t₃″. For example, the control logic circuit 30 may switch the third switch SW_{DISCH} off and the logic circuit 300 may switch the first switch SW_{S} on when the first output voltage V_{OUTP} drops to predefined a threshold value (e.g. 110% of V_{INP}).

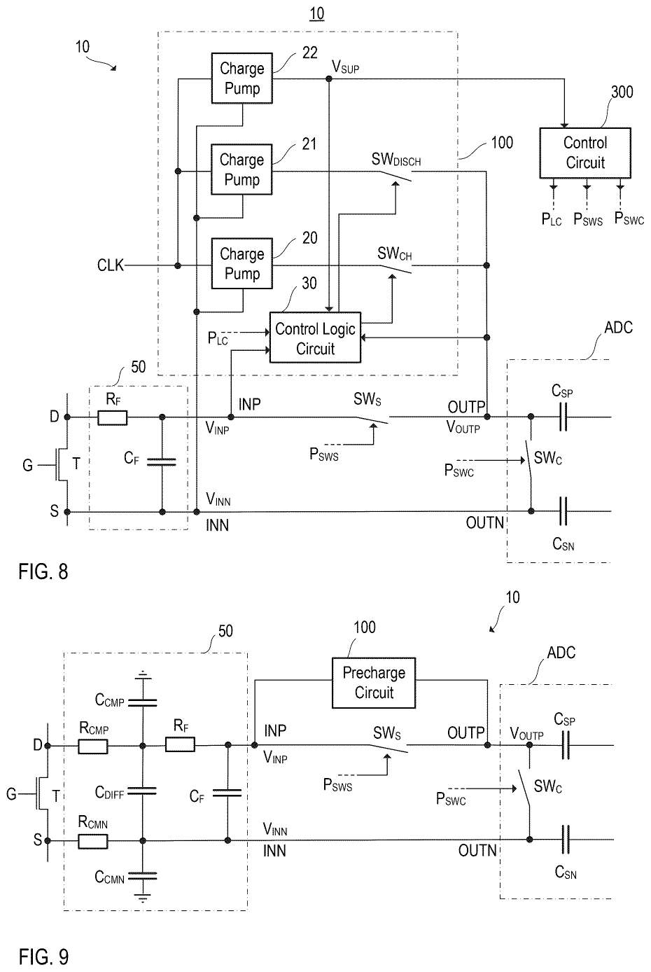

The circuit of FIG. 8 is basically the same like in FIG. 5, but with an additional third charge pump 22 provided in the pre-charge circuit 100. The third charge pump 22 is coupled to the control logic circuit 30 and the control circuit 300. The third charge pump 22 is also coupled to the second input node INN and to the clock signal CLK. The third charge pump 22 may have a similar structure as the first charge pump 20 shown in FIG. 4. The third charge pump 22 may be configured to provide a supply voltage V_{SUP} to the control logic circuit 30 and the control circuit 300. Since (part of) the logic, such as the second and third switch SW_{CH} and SW_{DISCH}, may need to operate in the floating voltage domain, providing the supply voltage V_{SUP} in the same voltage domain avoids the need for a sophisticated additional supply circuitry. It is understood that instead of the third charge pump 22 a current source may also be used. The same applies accordingly to the first and second charge pump 20 and 21, which may also be replaced by a current source respectively. Various implementations of current sources are as such known and are therefore not further discussed herein in more detail.

FIG. 9 is basically the same like in FIG. 1, but shows a modification of the filter 50. The control circuit 300 is not shown in FIG. 9 to keep the illustration simple. The filter 50 comprises, like in FIG. 1, an RC-circuit with an input resistance R_{F} and an input capacitor C_{F} (filter capacitor). Additionally, the filter 50 comprises a first and second common mode capacitor C_{CMP} and C_{CMN}, a differential filter capacitor C_{DIFF} and a first and second resistor R_{CMP} and R_{CMN}. The first resistor R_{CMP} is coupled between a drain node of the MOSFET T and a common circuit node of the differential filter capacitor C_{DIFF}, the filter resistor R_{F} and the first common mode capacitor C_{CMP}. The second resistor R_{CMN} is coupled between a source node of the MOSFET T and a common circuit node of the differential filter capacitor C_{DIFF}, the second common mode capacitor C_{CMN} and the second input node INN. The first and second common mode capacitors C_{CMP} and C_{CMN} are also coupled to a reference node, such as ground. The filter 50 in the example of FIG. 9 is implemented as a fully differential filter. The resistor R_{CMP} and the capacitor C_{CMP} as well as the resistor R_{CMN} and the capacitor C_{CMN} form two passive RC filter stages with regard to the common mode voltage. The resistors R_{CMP} and R_{CMN} and the capacitor C_{DIFF} form an RC filter stage with regard to the differential input voltage. The filtered input voltage is applied to the differential input (nodes INP, INN) of the electronic circuit 10.

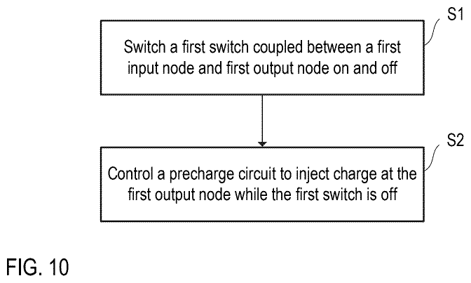

The concept described herein is further described with reference to the flow chart of FIG. 10, which illustrates a method that may be used to pre-charge a capacitor (e.g. C_{SP}). In the depicted example, the method includes switching a first switch SW_{S} coupled between a first input node INP and first output node OUTP on and off (see FIG. 10, box S1). The first input node INP and a second input node INN may form a differential input coupled to an input capacitor C_{F}, and the first output node OUTP and a second output node OUTN may form a differential output coupled to an output capacitor C_{SP} (see also FIG. 1). The method further includes controlling a pre-charge circuit 100 to inject charge at the first output node OUTP while the first switch SW_{S} is off (see FIG. 10, box S2; see also FIGS. 1 and 4).

Although the invention has been illustrated and described with respect to one or more implementations, alterations and/or modifications may be made to the illustrated examples without departing from the spirit and scope of the appended claims. In particular regard to the various functions performed by the above described components or structures (units, assemblies, devices, circuits, systems, etc.), the terms (including a reference to a “means”) used to describe such components are intended to correspond-unless otherwise indicated-to any component or structure, which performs the specified function of the described component (e.g., that is functionally equivalent), even though not structurally equivalent to the disclosed structure, which performs the function in the herein illustrated exemplary implementations of the invention.

1. An electronic circuit comprising:
a differential input including a first input node and a second input node and coupled, during operation, to an input capacitor;
a differential output including a first output node and a second output node and coupled, during operation, to an output capacitor;
a first switch coupled between the first input node and the first output node;
a pre-charge circuit configured to inject charge at the first output node; and
a control circuit configured to:
switch the first switch on and off; and
control the pre-charge circuit to inject charge at the first output node while the first switch is off.

2. The electronic circuit of claim 1,
wherein the second input node and the second output node are connected by a low-ohmic line.

3. The electronic circuit of claim 1,
wherein the control circuit is configured to control the pre-charge circuit to inject charge at the first output node as long as a differential input voltage is lower than a differential output voltage.

4. The electronic circuit of claim 1,
wherein the control circuit is configured to control the pre-charge circuit to inject charge at the first output node as long as a differential output voltage is lower than a defined threshold value.

5. The electronic circuit of claim
wherein the pre-charge circuit includes a first charge pump coupled to the first output node and configured to inject charge at the first output node.

6. The electronic circuit of claim 5,
wherein the control circuit is configured to activate and deactivate the charge pump based on a voltage at the first input node and a voltage at the first output node.

7. The electronic circuit of claim 6,
wherein the control circuit is configured to activate and deactivate the first charge pump by connecting the first charge pump to the first output node and, respectively, disconnecting the first charge pump from the first output node via a second switch.

8. The electronic circuit of claim 5
wherein the control circuit is configured to activate the first charge pump at a first time instant and deactivate the first charge pump at a second time instant, at which the voltage at the first output node reaches the voltage at the first input node.

9. The electronic circuit of claim 5
wherein the control circuit is configured to activate the first charge pump at a first time instant and deactivate the first charge pump at a threshold time instant, at which the voltage at the first output node reaches a defined threshold value.

10. The electronic circuit of claim 8
wherein the pre-charge circuit includes a comparator configured to detect the second time instant.

11. The electronic circuit of claim 5
wherein the pre-charge circuit includes a second charge pump coupled to the first output node and configured to sink charge from the first output node.

12. The electronic circuit of claim 11,
wherein the control circuit is configured to activate the second charge pump after deactivation of the first charge pump to compensate for an overshoot in the voltage at the first output node.

13. The electronic circuit of claim 5
wherein the control circuit comprises a control logic circuit and
wherein the pre-charge circuit further includes a third charge pump which is configured to provide a supply voltage for the control logic circuit.

14. The electronic circuit of claim 13,
wherein the control circuit is referenced to ground level and the control logic circuit is floating and referenced to a potential present at the first input node.

15. A system comprising:
an electronic circuit comprising:
a differential input including a first input node and a second input node and coupled, during operation, to an input capacitor;
a differential output including a first output node and a second output node and coupled, during operation, to an output capacitor;
a first switch coupled between the first input node and the first output node;
a pre-charge circuit configured to inject charge at the first output node; and
a control circuit configured to:
switch the first switch on and off; and
control the pre-charge circuit to inject charge at the first output node while the first switch is off, and
an analog-to-digital converter having a differential input that is coupled to the differential output of the electronic circuit
wherein the output capacitor of the electronic circuit is formed by the input capacitance of the analog-to-digital converter.

16. A method comprising:
switching a first switch coupled between a first input node and a first output node on and off, wherein the first input node and a second input node form a differential input coupled to an input capacitor, and wherein the first output node and a second output node form a differential output coupled to an output capacitor; and
controlling a pre-charge circuit to inject charge at the first output node while the first switch is off.

17. The method of claim 16,
wherein injecting charge at the first output node includes injecting current into the first output node to charge the output capacitor until a first output voltage at the first output node reaches a threshold value.

18. The method of claim 17,
wherein the threshold value is equal to, or lower than, a first input voltage at the first input node

19. The method of claim 17,
wherein injecting charge at the first output node further includes sinking current from the first output node to discharge the output capacitor and to compensate for an overshoot of the first output voltage.

20. The method of claim 16,
wherein injecting charge at the first output node includes:
injecting current into the first output node to charge the output capacitor until a first output voltage at the first output node reaches a target value, which is greater than a first input voltage at the first input node; and
sinking current from the first output node to discharge the output capacitor until the first output voltage reaches a threshold value.

21. The method of claim 20,
wherein the threshold value is substantially equal to the first input voltage
